(19) United States
(12) Patent Application Publication
(10) Pub. No.: US 2019/0181167 A1
(43) Pub. Date: Jun. 13, 2019

(54) BACKSIDE ILLUMINATED IMAGE SENSOR AND METHOD OF MANUFACTURING THE SAME

(71) Applicant: DB HITEK CO., LTD., Seoul (KR)

(72) Inventor: In Guen YEO, Seoul (KR)

(21) Appl. No.: 16/219,055

(22) Filed: Dec. 13, 2018

(30) Foreign Application Priority Data
Dec. 13, 2017 (KR) 10-2017-0171029

(51) Int. Cl. H01L 27/146

(52) U.S. Cl. CPC H01L 27/1464; H01L 27/14629; H01L 27/14621; H01L 27/14685; H01L 27/14636

(57) ABSTRACT

A backside illuminated image sensor includes charge accumulation regions disposed in a substrate, an insulating layer disposed on a frontside surface of the substrate, light reflection patterns disposed on the insulating layer to correspond to the charge accumulation regions, an anti-reflective layer disposed on a backside surface of the substrate, a light-blocking pattern disposed on the anti-reflective layer and having openings corresponding to the charge accumulation regions, a color filter layer disposed on the light-blocking pattern, and a micro lens array disposed on the color filter layer.

### CROSS-REFERENCE TO RELATED APPLICATION

This application claims the priority benefit of Korean Patent Application No. 10-2017-0171029, filed on Dec. 13, 2017, and all the benefits accruing therefrom under 35 U.S.C. § 119, the contents of which are incorporated by reference in their entirety.

### TECHNICAL FIELD

The present disclosure relates to a generally to the field of image sensors and in particular to the field of backside illuminated image sensors a methods of manufacturing the same.

### BACKGROUND

The present disclosure relates to a backside illuminated image sensor and a method of manufacturing the same.

In general, an image sensor is a semiconductor device that converts an optical image into electrical signals, and may be classified or categorized as a Charge Coupled Device (CCD) or a CMOS Image Sensor (CIS).

The CIS includes unit pixels, each including a photodiode and MOS transistors. The CIS sequentially detects the electrical signals of the unit pixels using a switching method, thereby forming an image. The CIS may be classified into a frontside illuminated image sensor and a backside illuminated image sensor.

A front side illuminated (or front-illuminated) image sensor may include photodiodes formed in a substrate, transistors formed on a front surface of the substrate, wiring layers formed on the front surface of the substrate, and a color filter layer and micro lens array formed on the wiring layers.

The backside illuminated (or back-illuminated) image sensor may have an improved light-receiving efficiency in comparison with the frontside illuminated image sensor. The backside illuminated image sensor may include transistors and wiring layers formed on a frontside surface of a substrate, a light-blocking pattern and an anti-reflective layer formed on a backside surface of the substrate, a passivation layer formed on the light-blocking pattern and the anti-reflective layer, and a color filter layer and a micro lens array formed on the passivation layer.

### SUMMARY

The present disclosure provides a backside illuminated image sensor having improved sensitivity and a method of manufacturing the backside illuminated image sensor.

In accordance with an aspect of the present disclosure, a backside illuminated image sensor may include charge accumulation regions disposed in a substrate, an insulating layer disposed on a frontside surface of the substrate, light reflection patterns disposed on the insulating layer to correspond to the charge accumulation regions, an anti-reflective layer disposed on a backside surface of the substrate, a light-blocking pattern disposed on the anti-reflective layer and having openings corresponding to the charge accumulation regions, a color filter layer disposed on the light-blocking pattern, and a micro lens array disposed on the color filter layer.

In accordance with some exemplary embodiments of the present disclosure, the backside illuminated image sensor may further include an etch stop layer disposed on the insulating layer, a second insulating layer disposed on the etch stop layer, and wiring patterns disposed on the second insulating layer and electrically connected with the charge accumulation regions.

In accordance with some exemplary embodiments of the present disclosure, the etch stop layer and the second insulating layer may have second openings corresponding to the charge accumulation regions, and the light reflection patterns may be disposed in the second openings.

In accordance with some exemplary embodiments of the present disclosure, the light reflection patterns may include tungsten.

In accordance with some exemplary embodiments of the present disclosure, the backside illuminated image sensor may further include contact plugs connected with the wiring patterns through the insulating layer, the etch stop layer and the second insulating layer. The light reflection patterns may be made of the same material as the contact plugs.

In accordance with some exemplary embodiments of the present disclosure, the light reflection patterns may include aluminum or copper.

In accordance with some exemplary embodiments of the present disclosure, the backside illuminated image sensor may further include wiring patterns disposed on the insulating layer and electrically connected with the charge accumulation regions. The light reflection patterns may be made of the same material as the wiring patterns.

In accordance with some exemplary embodiments of the present disclosure, the backside illuminated image sensor may further include frontside pinning layers disposed between the frontside surface of the substrate and the charge accumulation regions, and backside pinning layers disposed between the backside surface of the substrate and the charge accumulation region.

In accordance with some exemplary embodiments of the present disclosure, the backside illuminated image sensor may further include a passivation layer disposed on the anti-reflective layer and the light-blocking pattern.

In accordance with some exemplary embodiments of the present disclosure, the backside illuminated image sensor may further include a diffusion barrier layer disposed on the anti-reflective layer and the light-blocking pattern.

In accordance with another aspect of the present disclosure, a method of manufacturing a backside illuminated image sensor may include forming charge accumulation regions in a substrate, forming an insulating layer on a frontside surface of the substrate, forming light reflection patterns on the insulating layer to correspond to the charge accumulation regions, forming an anti-reflective layer on a backside surface of the substrate, forming a light-blocking pattern having openings corresponding to the charge accumulation regions on the anti-reflective layer, forming a color filter layer on the light-blocking pattern, and forming a micro lens array on the color filter layer.

In accordance with some exemplary embodiments of the present disclosure, the method may further include forming an etch stop layer on the insulating layer, forming a second insulating layer on the etch stop layer, and partially removing the second insulating layer and the etch stop layer to form second openings corresponding to the charge accumulation regions. The light reflection patterns may be formed in the second openings.

In accordance with some exemplary embodiments of the present disclosure, the method may further include forming wiring patterns on the second insulating layer, the wiring patterns being electrically connected with the charge accumulation regions.

In accordance with some exemplary embodiments of the present disclosure, the method may further include forming contact holes through the second insulating layer, the etch stop layer and the insulating layer, and forming contact plugs in the contact holes. The light reflection patterns may be simultaneously formed with the contact plugs, and the wiring patterns may be connected with the contact plugs.

In accordance with some exemplary embodiments of the present disclosure, the light reflection patterns may include tungsten.

In accordance with some exemplary embodiments of the present disclosure, the method may further include forming wiring patterns on the insulating layer, the wiring patterns being electrically connected with the charge accumulation regions. The light reflection patterns may be simultaneously formed with the wiring patterns.

In accordance with some exemplary embodiments of the present disclosure, the light reflection patterns may include aluminum or copper.

In accordance with some exemplary embodiments of the present disclosure, the method may further include forming frontside pinning layers between the frontside surface of the substrate and the charge accumulation regions, and forming backside pinning layers between the backside surface of the substrate and the charge accumulation region.

In accordance with some exemplary embodiments of the present disclosure, the method may further include forming a passivation layer on the anti-reflective layer and the light-blocking pattern. The color filter layer may be formed on the passivation layer.

In accordance with some exemplary embodiments of the present disclosure, the method may further include forming a diffusion barrier layer on the anti-reflective layer and the light-blocking pattern. The passivation layer may be formed on the diffusion barrier layer.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Exemplary embodiments can be understood in more detail from the following description taken in conjunction with the accompanying drawings, in which:

FIG. 1 is a cross-sectional view illustrating a backside illuminated image sensor in accordance with an of the present disclosure;

FIG. 2 is a cross-sectional view illustrating a backside illuminated image sensor in accordance with another embodiment of the present disclosure;

FIGS. 3 to 13 are cross-sectional views illustrating a method of manufacturing the backside illuminated image sensor as shown in FIG. 1; and

FIGS. 14 to 18 are cross-sectional views illustrating a method of manufacturing the backside illuminated image sensor as shown in FIG. 2.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF THE DRAWINGS

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

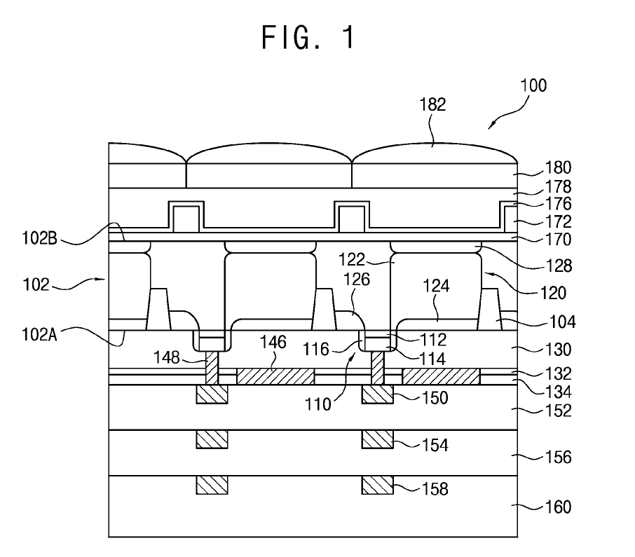

FIG. 1 is a cross-sectional view illustrating a backside illuminated image sensor in accordance with an exemplary embodiment of the present disclosure.

Referring to FIG. 1, a backside illuminated image sensor 100, in accordance with an exemplary embodiment of the present disclosure, may include pixel regions 120 disposed in a substrate 102. Each of the pixel regions 120 may include a charge accumulation region 122 in which charges generated by the incident light are accumulated. The charge accumulation regions 122 may be disposed in the substrate 102, and floating diffusion regions 126 may be disposed in frontside surface portions of the substrate 102 and spaced apart from the charge accumulation regions 122.

The substrate 102 may have a first conductivity type, and the charge accumulation regions 122 and the floating diffusion regions 126 may have a second conductivity type. For example, a p-type substrate may be used as the substrate 102, and n-type impurity diffusion regions functioning as the charge accumulation regions 122 and the floating diffusion regions 126 may be formed in the p-type substrate 102.

Transfer gate structures 110 may be disposed on channel regions between the charge accumulation regions 122 and the floating diffusion regions 126 to transfer the charges accumulated in the charge accumulation regions 122 to the floating diffusion regions 126. Each of the transfer gate structures 110 may include a gate insulating layer 112 disposed on a frontside surface 102A of the substrate 102, a gate electrode 114 disposed on the gate insulating layer 112, and gate spacers 116 disposed on side surfaces of the gate electrode 114. Further, though not shown in figures, the backside illuminated image sensor 100 may include reset transistors, source follower transistors, and select transistors electrically connected with the floating diffusion regions 126.

Alternatively, if the backside illuminated image sensor 100 is a 3T (in other words, a device with fewer than three transistors) layout, the transfer gate structures 110 may be used as reset gate structures, and the floating diffusion regions 126 may be used as active regions for connecting the charge accumulation regions 122 with reset circuitries.

The pixel regions 120 may include a frontside pinning layer 124 disposed between the frontside surface 102A of the substrate 102 and the charge accumulation regions 122. Further, the pixel regions 120 may include a backside pinning layer 128 disposed between a backside surface 102B of the substrate 102 and the charge accumulation regions 122, respectively. The frontside and backside pinning layers 124 and 128 may have the first conductivity type. For example, p-type impurity diffusion regions may be used as the frontside and backside pinning layers 124 and 128.

In accordance with an exemplary embodiment of the present disclosure, an insulating layer 130 may be disposed on the frontside surface 102A of the substrate 102 and the transfer gate structures 110, and light reflection patterns 146 corresponding to the charge accumulation regions 122 may be disposed on an insulating layer 130. The light reflection patterns 146 may reflect the light passing through the charge accumulation regions 122 in order to return the light to the charge accumulation regions 122.

For example, an etch stop layer 132 may be disposed on the insulating layer 130, and a second insulating layer 134 may be disposed on the etch stop layer 132. Particularly, the etch stop layer 132 and the second insulating layer 134 may have openings 138 (refer to FIG. 7) corresponding to the charge accumulation regions 122, and the light reflection patterns 146 may be disposed in the openings 138. The insulating layer 130 and the second insulating layer 134 may be made of silicon oxide, and the etch stop layer 132 may be made of silicon nitride, in one embodiment.

Wiring patterns 150 electrically connected with the charge accumulation regions 122 may be disposed on the second insulating layer 134. For example, the wiring patterns 150 may be electrically connected with the charge accumulation regions 122 by contact plugs 148 passing through the insulating layer 130, the etch stop layer 132 and the second insulating layer 134. Particularly, the light reflection patterns 146 may be made of the same material as the contact plugs 148. For example, the light reflection patterns 146 and the contact plugs 148 may both be made of tungsten in one embodiment.

Second wiring patterns 154 and third wiring patterns 158 may be disposed on the wiring patterns 150. Particularly, a first interlayer insulating layer 152 may be disposed between the wiring patterns 150 and the second wiring patterns 154, and a second interlayer insulating layer 156 may be disposed between the second wiring patterns 154 and the third wiring patterns 158. Further, a third insulating layer 160 may be disposed on the third wiring patterns 158.

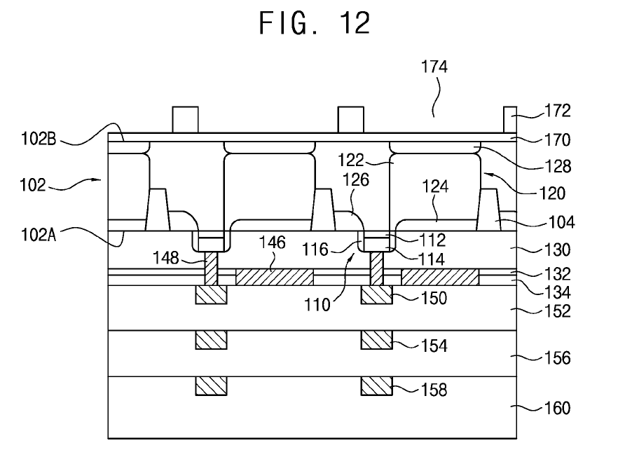

An anti-reflective layer 170 may be disposed on the backside surface 102B of the substrate 102, and a light-blocking pattern 172 having openings 174 (refer to FIG. 12) corresponding to the charge accumulation regions 122 may be disposed on the anti-reflective layer 170. Further, a passivation layer 178 may be disposed on the anti-reflective layer 170 and the light-blocking pattern 172, a color filter layer 180 may be disposed on the passivation layer 178, and a micro lens array 182 may be disposed on the color filter layer 180. Meanwhile, the pixel regions 120 may be electrically isolated with one another by pixel isolation regions 104.

The light-blocking pattern 172 may be used to reduce the light loss and the crosstalk of the backside illuminated image sensor 100 and may be made of a metal such as tungsten. Particularly, a diffusion barrier layer 176 may be disposed on the anti-reflective layer 170 and the light-blocking pattern 172, and the passivation layer 178 may be disposed on the diffusion barrier layer 176. For example, the anti-reflective layer 170 and the diffusion barrier layer 176 may be made of silicon nitride, and the passivation layer 178 may be made of silicon oxide.

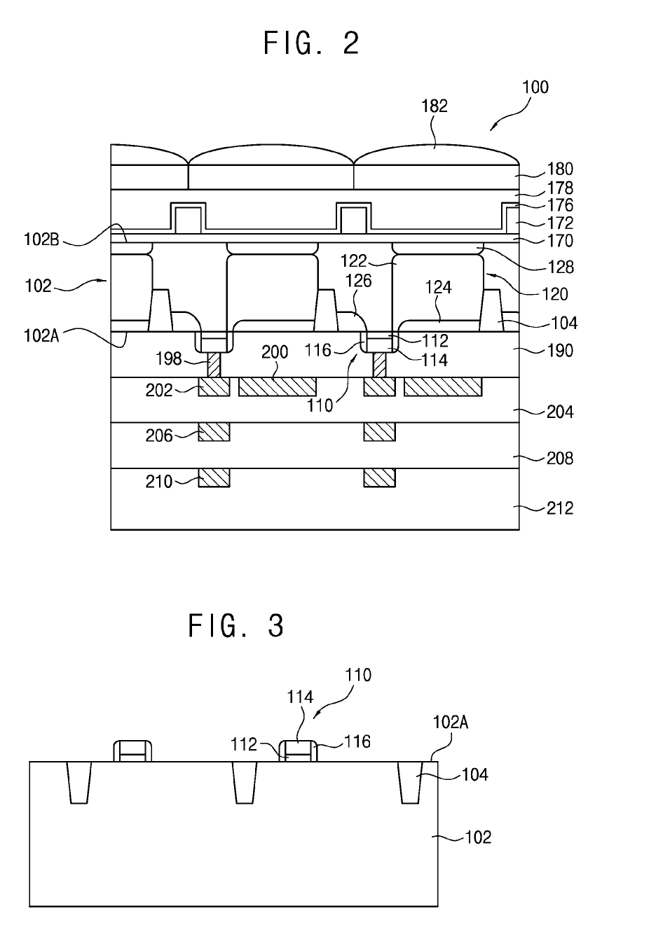

FIG. 2 is a cross-sectional view illustrating a backside illuminated image sensor in accordance with another exemplary embodiment of the present disclosure. Common reference numbers (e.g., 102A and 102B) are used to refer to like parts, though it should be understood that these parts are arranged in a different configuration than those of FIG. 1.

Referring to FIG. 2, in accordance with another exemplary embodiment of the present disclosure, an insulating layer 190 may be disposed on a frontside surface 102A of a substrate 102 and transfer gate structures 110, and light reflection patterns 200 corresponding to charge accumulation regions 122 may be disposed on the insulating layer 190. Further, wiring patterns 202 may be disposed on the insulating layer 190, and may be electrically connected with the charge accumulation regions 122 by contact plugs 198 passing through the insulating layer 190.

Particularly, the light reflection patterns 200 may be made of the same material as the wiring patterns 202, and may be simultaneously formed with the wiring patterns 202. For example, the light reflection patterns 200 and the wiring patterns 202 may be made of aluminum or copper.

A first interlayer insulating layer 204 may be disposed on the light reflection patterns 200, the wiring patterns 202 and the insulating layer 190, and second wiring patterns 206 may be disposed on the first interlayer insulating layer 204. A second interlayer insulating layer 208 may be disposed on the first interlayer insulating layer 204 and the second wiring patterns 206, and third wiring patterns 210 may be disposed on the second interlayer insulating layer 208. A second insulating layer 212 may be disposed on the second interlayer insulating layer 208 and the third wiring patterns 210.

FIGS. 3 to 13 are cross-sectional views illustrating a method of manufacturing the backside illuminated image sensor 100 as shown in FIG. 1.

Referring to FIG. 3, pixel isolation regions 104 may be formed in frontside surface portions of a substrate 102 to define active regions of the backside illuminated image sensor 100. The substrate 102 may have a first conductivity type. For example, a p-type substrate may be used as the substrate 102. Alternatively, the substrate 102 may include a bulk silicon substrate and a p-type epitaxial layer formed on the bulk silicon substrate. The pixel isolation regions 104 may be made of silicon oxide and may be formed by a shallow trench isolation (STI) process in one embodiment.

After forming the pixel isolation regions 104, transfer gate structures 110 may be formed on a frontside surface 102A of the substrate 102. Each of the transfer gate structures 110 may include a gate insulating layer 112, a gate electrode 114 formed on the gate insulating layer 112, and gate spacers 116 formed on side surfaces of the gate electrode 114. Further, though not shown in figures, reset gate structures, source follower gate structures and select gate structures may be simultaneously formed with the transfer gate structures 110 on the frontside surface 102A of the substrate 102 in some embodiments.

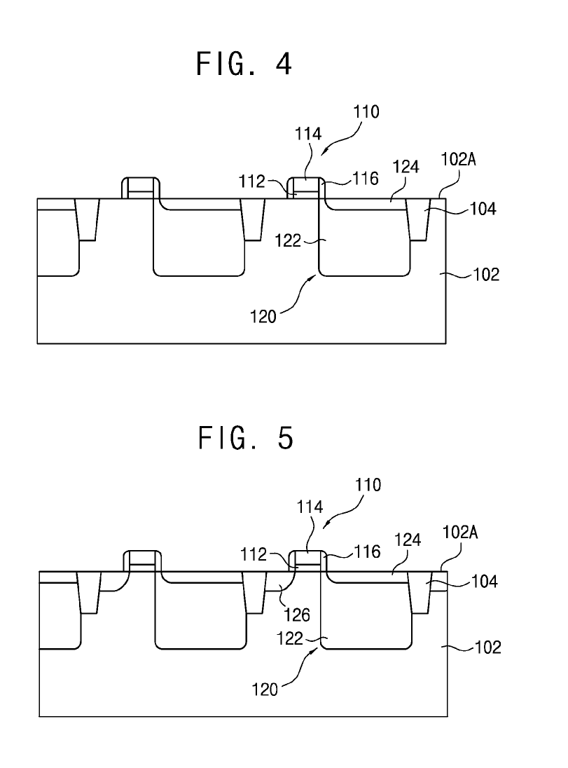

Referring to FIG. 4, charge accumulation regions 122 used as pixel regions 120 may be formed in the substrate 102. In detail, charge accumulation regions 122 having a second conductivity type may be formed in the active regions of the substrate 102. For example, n-type charge accumulation regions 122 may be formed in the p-type substrate 102. The n-type charge accumulation regions 122 may be n-type impurity diffusion regions formed by an ion implantation process, for example.

Frontside pinning layers 124 having the first conductivity type may be formed between the frontside surface 102A of the substrate 102 and the charge accumulation regions 122. For example, p-type frontside pinning layers 124 may be formed between the frontside surface 102A of the substrate 102 and the n-type charge accumulation regions 122 by an ion implantation process. The p-type frontside pinning layers 124 may be p-type impurity diffusion regions. The n-type charge accumulation regions 122 and the p-type frontside pinning layers 124 may be activated by a subsequent rapid heat treatment process.

Referring to FIG. 5, floating diffusion regions 126 having the second conductivity type may be formed in frontside surface portions of the substrate 102 to be spaced apart from the charge accumulation regions 122. For example, the floating diffusion regions 126 may be n-type high concentration impurity regions, which may be formed by an ion implantation process. At this time, the transfer gate structures 110 may be arranged on channel regions between the charge accumulation regions 122 and the floating diffusion regions 126.

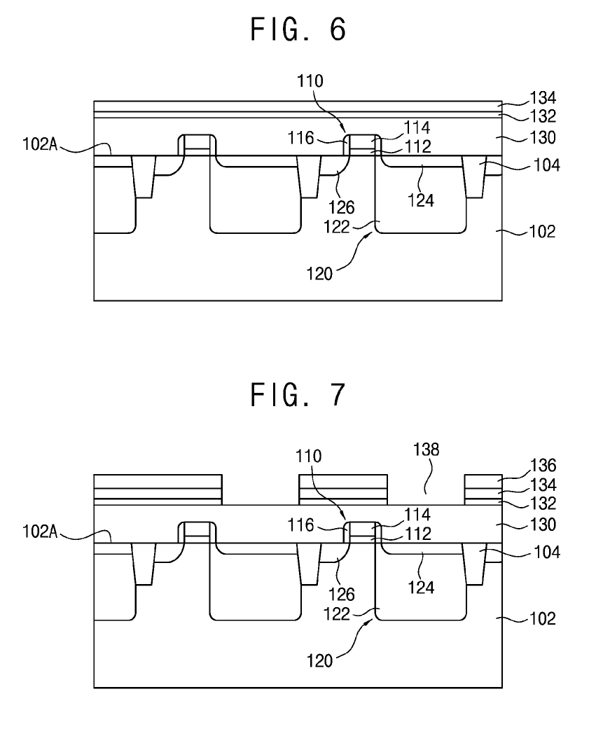

Referring to FIG. 6, an insulating layer 130 may be formed on the frontside surface 102A of the substrate 102 and the transfer gate structures 110. Further, an etch stop layer 132 may be formed on the insulating layer 130, and a second insulating layer 134 may be formed on the etch stop layer 132. For example, the insulating layer 130 and the second insulating layer 134 may be made of silicon oxide, and the etch stop layer 132 may be made of silicon nitride.

Referring to FIG. 7, a first photoresist pattern 136 may be formed on the second insulating layer 134, and openings 138 exposing portions of the insulating layer 130 may then be formed by an anisotropic etching process using the first photoresist pattern 136 as an etching mask. That is, the second insulating layer 134 and the etch stop layer 132 may be partially removed by the anisotropic etching process, and the openings 138 exposing the portions of the insulating layer 130 may thus be formed. Particularly, the openings 138 may be formed to correspond to the charge accumulation regions 122. The first photoresist pattern 136 may be removed by an ashing or strip process after forming the openings 138.

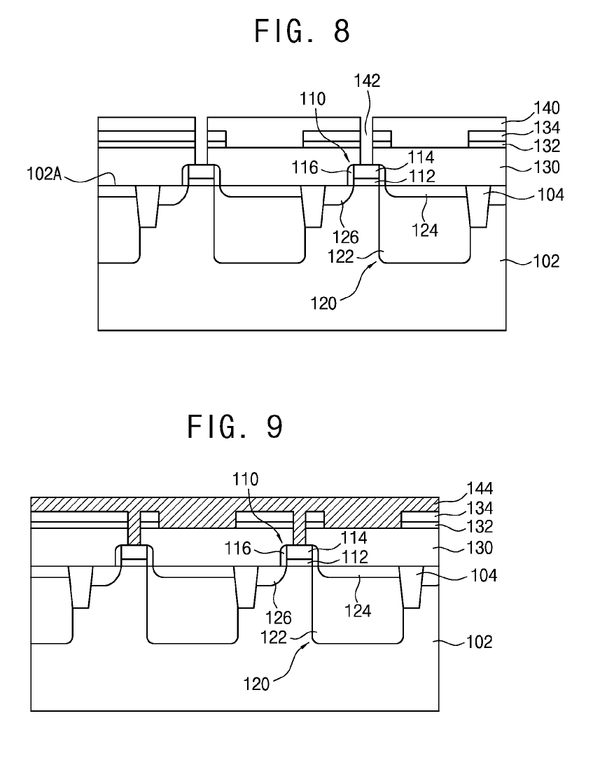

Referring to FIG. 8, a second photoresist pattern 140 may be formed on the second insulating layer 134, and contact holes 142 connected with the transfer gate structures 110 may then be formed by an anisotropic etching process using the second photoresist pattern 140 as an etching mask. That is, the second insulating layer 134, the etch stop layer 132 and the insulating layer 130 may be partially removed by the anisotropic etching process, and the contact holes 142 may thus be formed. Further, contact holes, which are connected with the floating diffusion regions 126, reset transistors, source follower transistors, select transistors, and the like, may be formed by the anisotropic etching process using the second photoresist pattern 140. The second photoresist pattern 140 may be removed by an ashing or strip process after forming the contact holes 142.

Referring to FIG. 9, a metal layer 144 may be formed on the second insulating layer 134 so that the openings 138 and the contact holes 142 are buried. For example, a tungsten layer 144 may be formed on the second insulating layer 134 by a metal organic chemical vapor deposition (MOCVD) process, and thus the openings 138 and the contact holes 142 may be filled with tungsten.

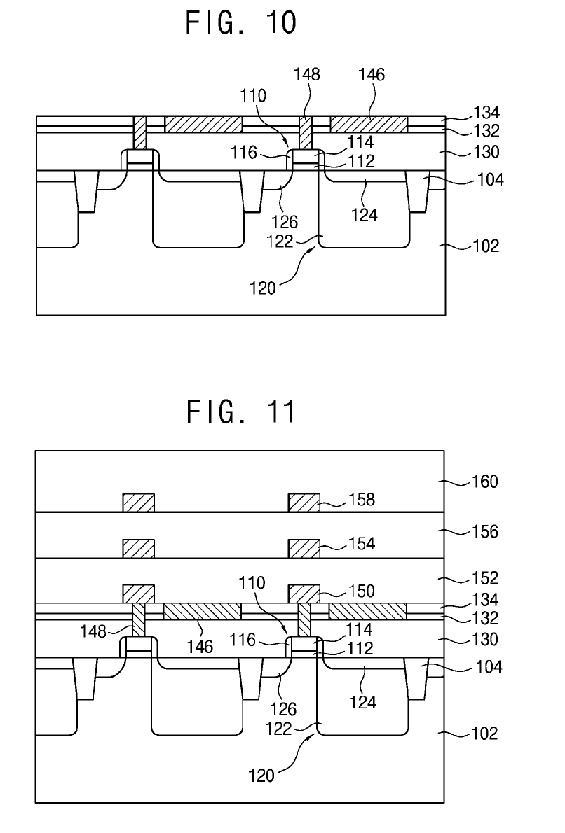

Referring to FIG. 10, a planarization process may be performed so that the second insulating layer 134 is exposed, thereby forming light reflection patterns 146 and contact plugs 148 in the openings 138 and the contact holes 142, respectively. For example, a Chemical Mechanical Polish (CMP) process may be performed so that the second insulating layer 134 is exposed. That is, an upper portion of the tungsten layer 144 may be removed by the CMP process, and the light reflection patterns 146 and the contact plugs 148 may thus be formed in the openings 138 and the contact holes 142, respectively.

Referring to FIG. 11, wiring patterns 150 electrically connected with the charge accumulation regions 122 may be formed on the second insulating layer 134. For example, the wiring patterns 150 may be made of aluminum or copper.

A first interlayer insulating layer 152 may be formed on the second insulating layer 134, the light reflection patterns 146 and the wiring patterns 150, and second wiring patterns 154 may be formed on the first interlayer insulating layer 152. A second interlayer insulating layer 156 may be formed on the first interlayer insulating layer 152 and the second wiring patterns 154, and third wiring patterns 155 may be formed on the second interlayer insulating layer 156. Further, a third insulating layer 160 may be formed on the second interlayer insulating layer 156 and the third wiring patterns 158. For example, the first and second interlayer insulating layers 152 and 156 and the third insulating layer 160 may be made of silicon oxide, and the second and third wiring patterns 154 and 158 may be made of aluminum or copper.

Referring to FIG. 12, a back-grinding process or a chemical and mechanical polishing process may be performed in order to reduce a thickness of the substrate 102. Further, backside pinning layers 128 having the first conductivity type may be formed between a backside surface 102B of the substrate 102 and the charge accumulation regions 122. For example, p-type impurity regions functioning as the backside pinning layers 128 may be formed by an ion implantation process, and may then be activated by a subsequent laser annealing process.

Alternatively, the backside pinning layers 128 may be formed prior to the charge accumulation regions 122. For example, after forming the backside pinning layers 128, the charge accumulation regions 122 may be formed on the backside pinning layers 128, and the frontside pinning layers 124 may then be formed on the charge accumulation regions 122. In such case, the backside pinning layers 128 may be activated by the rapid heat treatment process along with the charge accumulation regions 122 and the frontside pinning layers 124. Further, the back-grinding process may be performed such that the backside pinning layers 128 are exposed.

Then, an anti-reflective layer 170 may be formed on the backside surface 102B of the substrate 102, and a light-blocking pattern 172 may then be formed on the anti-reflective layer 170. For example, the anti-reflective layer 170 may be formed of silicon nitride, and the light-blocking pattern 172 may be formed of a metal such as tungsten. Particularly, the light-blocking pattern 172 may have openings 174 corresponding to the charge accumulation regions 122 and may be used to improve the crosstalk of the backside illuminated image sensor 100. For example, a tungsten layer (not shown) may be formed on the anti-reflective layer 170, and the light-blocking pattern 172 may then be formed by patterning the tungsten layer.

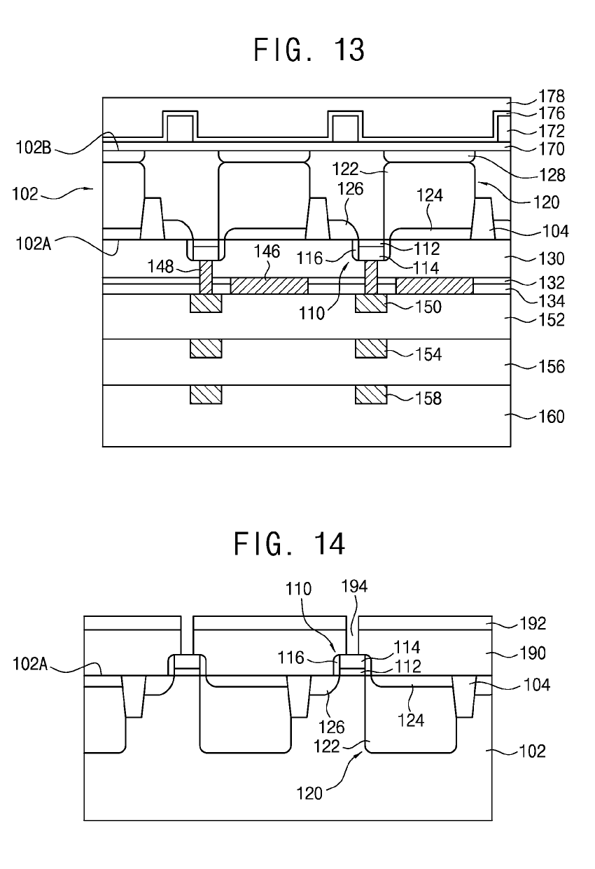

Referring to FIG. 13, a diffusion barrier layer 176 may be formed on the anti-reflective layer 170 and the light-blocking pattern 172, and a passivation layer 178 may be formed on the diffusion barrier layer 176. The diffusion barrier layer 176 may be used to prevent metal diffusion from the light-blocking pattern 172, this is, tungsten diffusion. For example, the diffusion barrier layer 176 may be made of silicon nitride, and the passivation layer 178 may be made of silicon oxide.

Then, as shown in FIG. 1, a color filter layer 180 and a micro lens array 182 may be sequentially formed on the passivation layer 178.

FIGS. 14 to 18 are cross-sectional views illustrating a method of manufacturing the backside illuminated image sensor 100 as shown in FIG. 2.

Referring to FIG. 14, after forming transfer gate structures 110 on a frontside surface 102A of a substrate 102, an insulating layer 190, e.g., a silicon oxide layer may be formed on the frontside surface 102A of the substrate 102 and the transfer gate structures 110. A photoresist pattern 192 may be formed on the insulating layer 190, and contact holes 194 connected with the transfer gate structures 110 may then be formed by an anisotropic etching process using the photoresist pattern 192 as an etching mask. At this time, contact holes, which are connected with floating diffusion regions 126, reset transistors, source follower transistors, select transistors, and the like, may be formed by the anisotropic etching process using the photoresist pattern 192. The photoresist pattern 192 may be removed by an ashing or strip process after forming the contact holes 194.

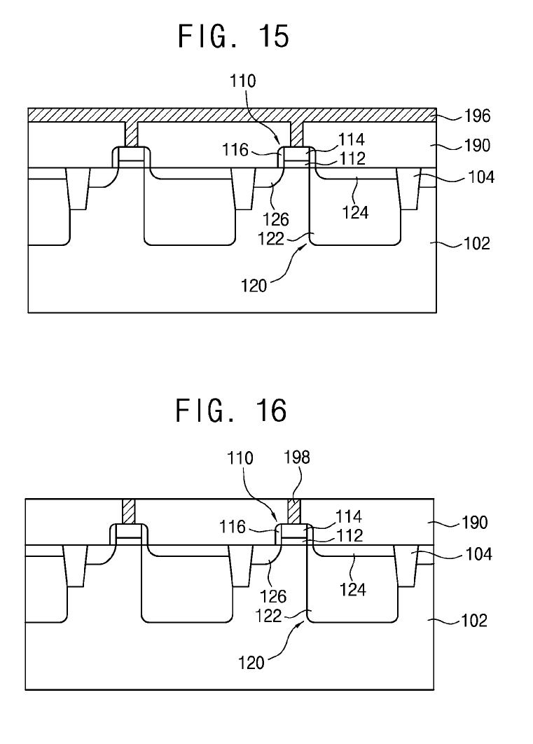

Referring to FIG. 15, a metal layer 196 may be formed on the insulating layer 190 so that the contact holes 194 are buried. For example, a tungsten layer 196 may be formed on the insulating layer 190 by a metal organic chemical vapor deposition process, and thus the contact holes 194 may be filled with tungsten.

Referring to FIG. 16, a planarization process may be performed so that the insulating layer 190 is exposed, thereby forming contact plugs 198 in the contact holes 194. For example, a CMP process may be performed so that the insulating layer 190 is exposed.

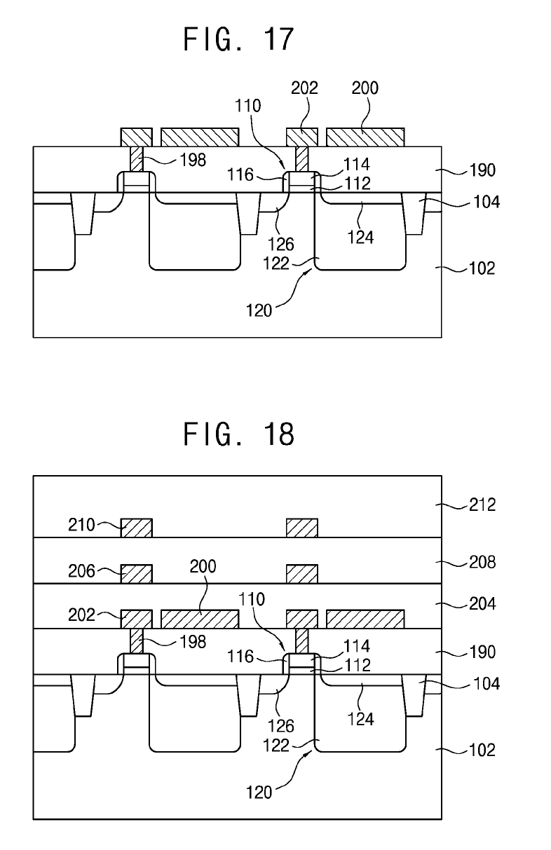

Referring to FIG. 17, light reflection patterns 200 corresponding to charge accumulation regions 122 and wiring patterns 202 electrically connected with the charge accumulation regions 122 may be formed on the insulating layer 190. For example, the light reflection patterns 200 and the wiring patterns 202 may be made of aluminum or copper and may be formed by an aluminum patterning process or a copper damascene process.

Referring to FIG. 18, a first interlayer insulating layer 204 may be formed on the insulating layer 190, the light reflection patterns 200 and the wiring patterns 202, and second wiring patterns 206 may be formed on the first interlayer insulating layer 204. A second interlayer insulating layer 208 may be formed on the first interlayer insulating layer 204 and the second wiring patterns 206, and third wiring patterns 210 may be formed on the second interlayer insulating layer 208. Further, a second insulating layer 212 may be formed on the second interlayer insulating layer 208 and the third wiring patterns 210. For example, the first and second interlayer insulating layers 204 and 208 and the second insulating layer 212 may be made of silicon oxide, and the second and third wiring patterns 206 and 210 may be made of aluminum or copper.

In accordance with the exemplary embodiments of the present disclosure as described above, the light passing through the charge accumulation regions 122 may return to the charge accumulation regions 122 by the light reflection patterns 146 or 200, and thus the sensitivity of the backside illuminated image sensor 100 may be significantly improved.

Although the backside illuminated image sensor 100 and the method of manufacturing the same have been described with reference to specific embodiments, they are not limited thereto. Therefore, it will be readily understood by those skilled in the art that various modifications and changes can be made thereto without departing from the spirit and scope of the present disclosure defined by the appended claims.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

1. A backside illuminated image sensor comprising:
a plurality of charge accumulation regions disposed in a substrate that defines a frontside surface and a backside surface opposite from the frontside surface;
an insulating layer disposed on the frontside surface of the substrate;
a plurality of light reflection patterns disposed on the insulating layer, each of the plurality of light reflection patterns corresponding to one of the plurality of charge accumulation regions;
an anti-reflective layer disposed on the backside surface of the substrate;
a light-blocking pattern disposed on the anti-reflective layer, the light-blocking pattern defining a plurality of openings, each of the openings corresponding to one of the charge accumulation regions;
a color filter layer disposed on the light-blocking pattern; and
a micro lens array disposed on the color filter layer.

2. The backside illuminated image sensor of claim 1, further comprising:
an etch stop layer disposed on the insulating layer;
a second insulating layer disposed on the etch stop layer; and
at least one wiring pattern disposed on the second insulating layer and electrically connected with the charge accumulation regions.

3. The backside illuminated image sensor of claim 2, wherein the etch stop layer and the second insulating layer define a second plurality of openings corresponding to the charge accumulation regions, and the light reflection patterns are disposed in the second plurality of openings.

4. The backside illuminated image sensor of claim 3, wherein the light reflection patterns comprise tungsten.

5. The backside illuminated image sensor of claim 2, further comprising:
a plurality of contact plugs electrically connected with the wiring patterns and extending through the insulating layer, the etch stop layer and the second insulating layer,
wherein the light reflection patterns are made of the same material as the contact plugs.

6. The backside illuminated image sensor of claim 1, wherein the light reflection patterns comprise aluminum or copper.

7. The backside illuminated image sensor of claim 1, further comprising:
at least one wiring pattern disposed on the insulating layer and electrically connected with the charge accumulation regions,
wherein the light reflection patterns are made of the same material as the at least one wiring pattern.

8. The backside illuminated image sensor of claim 1, further comprising:
a plurality of frontside pinning layers each disposed between the frontside surface of the substrate and the charge accumulation regions; and
a plurality of backside pinning layers each disposed between the backside surface of the substrate and the charge accumulation region.

9. The backside illuminated image sensor of claim 1, further comprising:
a passivation layer disposed on the anti-reflective layer and the light-blocking pattern.

10. The backside illuminated image sensor of claim 1, further comprising:
a diffusion barrier layer disposed on the anti-reflective layer and the light-blocking pattern.

11. A method of manufacturing a backside illuminated image sensor, the method comprising:
forming a plurality of charge accumulation regions in a substrate having a frontside surface and a backside surface opposite from the frontside surface;
forming an insulating layer on the frontside surface of the substrate;
forming a plurality of light reflection patterns on the insulating layer each corresponding to one of the plurality of charge accumulation regions;
forming an anti-reflective layer on the backside surface of the substrate;
forming a light-blocking pattern defining openings corresponding to the plurality of charge accumulation regions on the anti-reflective layer;
forming a color filter layer on the light-blocking pattern; and
forming a micro lens array on the color filter layer.

12. The method of claim 11, further comprising:
forming an etch stop layer on the insulating layer;
forming a second insulating layer on the etch stop layer; and
partially removing the second insulating layer and the etch stop layer to form a second plurality of openings corresponding to the charge accumulation regions,
wherein the light reflection patterns are formed in the second plurality of openings.

13. The method of claim 12, further comprising:
forming at least one wiring pattern on the second insulating layer, wherein the at least one wiring pattern is electrically connected with the plurality of charge accumulation regions.

14. The method of claim 13, further comprising:
forming contact holes through the second insulating layer, the etch stop layer and the insulating layer; and
forming contact plugs in the contact holes,
wherein the light reflection patterns are simultaneously formed with the contact plugs, and the wiring patterns are connected with the contact plugs.

15. The method of claim 12, wherein the light reflection patterns comprise tungsten.

16. The method of claim 11, further comprising:
forming a plurality of wiring patterns on the insulating layer, the plurality of wiring patterns each electrically connected with the charge accumulation regions,
wherein the light reflection patterns are simultaneously formed with the wiring patterns.

17. The method of claim 11, wherein the light reflection patterns comprise aluminum or copper.

18. The method of claim 11, further comprising:
forming a plurality of frontside pinning layers between the frontside surface of the substrate and the charge accumulation regions; and
forming a plurality of backside pinning layers between the backside surface of the substrate and the charge accumulation regions.

19. The method of claim 11, further comprising:
forming a passivation layer on the anti-reflective layer and the light-blocking pattern,
wherein the color filter layer is formed on the passivation layer.

20. The method of claim 19, further comprising:
forming a diffusion barrier layer on the anti-reflective layer and the light-blocking pattern,
wherein the passivation layer is formed on the diffusion barrier layer.
